(19) United States
(12) Patent Application Publication
(10) Pub. No.: US 2003/0112602 A1
(43) Pub. Date: Jun. 19, 2003

(54) Structure and designing method of composite heat-dissipating structure

(76) Inventor: Chieh-Wei Lin, Taoyuan Shien (TW)

Correspondence Address: Gazdzinski & Associates, Suite 375, 11440 West Bernardo Court, San Diego, CA, 92127, US

(21) Appl. No.: 10/350,878

(22) Filed: Jan. 23, 2003

Related U.S. Application Data
(63) Continuation-in-part of application No. 10/045,113, filed on Oct. 18, 2001, now abandoned.

(30) Foreign Application Priority Data
Apr. 6, 2001 (TW) 90205377

(51) Int. Cl. H05K 7/20; H01L 23/34

(52) U.S. Cl. 361/707; 257/719

(57) ABSTRACT

A composite heat-dissipating structure includes: a first heat-dissipating element detachably connected to a heat-generating device, and a second heat-dissipating element detachably connected to the first heat-dissipating element, wherein the first and second heat-dissipating elements are ones of standard pieces and portions of standard pieces and are flexibly assembled and changed without a necessity of redesigning a mold and a circuit board for the structure so as to dissipate a heat generated by the heat-generating device, and to meet space limitations for the heat-generating device being mounted on the first heat-dissipating element, for the first heat-dissipating element being mounted on the second heat-dissipating element, and for the second heat-dissipating element being mounted on the circuit board. A method of designing such a structure and a system with multiple such structures mounted on the same circuit board with all the second heat-dissipating elements in parallel with each other have also been proposed.

### FIELD OF THE INVENTION

The present invention is a CIP application of the parent application “Composite Heat-Dissipating Structure” bearing on the Ser. No. 10/045,113 and filed on Oct. 18, 2001. The present invention relates to a heat-dissipating structure, and more particularly to a composite heat-dissipating structure.

### BACKGROUND OF THE INVENTION

Along with the progression of technology, nowadays, the processing speed of the systemic host is increasingly faster. However, when the operating frequency is largely increased, the operating current is also increased, and the amount of heat generated by a heat-generating device on the circuit broad is higher too. The heat will cause a negative effect on the systemic stability of the integrated circuit. Therefore, it is an important issue to decrease the heat generated by the heat-generating device through the heat-dissipating element, especially in a server because it requires a relatively long-term operation.

FIGS. 1A-1C are diagrams illustrating a heat-dissipating structure according to the prior art. As shown in FIG. 1A, a thermal conductive plate 11 and a heat-generating device 10 are fixed on a circuit board (not shown). The thermal conductive plate 11 is used for dissipating the heat generated by the heat-generating device through heat conduction. However, the real amount of heat needed to be dissipated is usually larger than the estimated value according to the theory. Thus, once the estimated heat-dissipating value was found lower than the real value, a new die for manufacturing a new heat-dissipating element with a higher heat-dissipating effect such as the thermal conductive plate having a plurality of cooling fins 111 as shown in FIG. 1B is needed. However, if the requirement of the heat-dissipating amount goes up again, another new die for manufacturing a new heat-dissipating element, such as the heat sink with a one-piece shape of 111 plus 112 as shown in FIG. 1C is required in order to fit the space limitation on the circuit board. As to a different circuit board, a different heat sink might be necessary due to different layout of elements on the circuit board and different amount of heat generated by the heat-generating devices. Though, there are many inventions regarding heat sinks in the prior arts which has three elements connected by screws (Ogura et al. U.S. Pat. No. 5,191,512, Horton U.S. Pat. No. 4,720,771, Ashida et al. U.S. Pat. No. 6,067,230, and Japan Patent No. 2-278799 in view of Solberg U.S. Pat. No. 5,343,362) just like the previous patent application filed on Oct. 18, 2001 with a Ser. No. 10/045,113. With such a composite structure, the maintenance of the heat-generating device on a circuit board will be easier for each of the three components can be taken out easily by tearing down the connecting screws such that the broken heat-generating device on the circuit board can be changed. Thus, the maintenance costs will be decreased.

However, all of the inventions in the prior arts except for the present one will need a new design and a new mold for a new heat sink, or any of its element for heat-dissipating captioned above once a new application regarding a heat-generating device on a circuit board is appeared to save the manufacturing costs for producing such a new heat sink in large amount. Sometimes, even a new design of the circuit board is needed, if without any new heat sink which meets the heat-dissipating requirements could be fitted in the originally circuit board due to that the real heat generated by the heat-generating device is larger than the estimated value according to the theory, the space leaved for the heat sink is limited and there is no way that it can be changed. Actually, when talking about costs minimizing, the total costs of a new kind of heat sinks including the designing costs of a new heat sink, its die, and the manufacturing costs of a new die and the heat sinks (including the material costs and laboring cost etc.) should be minimized instead of only the manufacturing costs. When a new heat sink is designed and all the existing heat sinks, its elements, portions of the existing heat sinks, and portions of its elements are considered, then the relatively higher costs of a designer and a new mold are saved due to a much shorter time for the designing work and there is no need of a new die. Though the manufacturing costs of a new kind of heat sinks will be a little bit higher, due to the cutting, grinding and punching works that are needed when a portion of an existing heat sink or its element is used. However, the total costs for manufacturing such a new kind of heat sinks will definitely be much lower with a much shorter designing time and with no need of a new die. When the space is limited and no existing heat sinks can be fit in the space leaved on a circuit board for a heat-generating device, then a portion of an existing heat sink or a portion of its element will be considered. A portion of a existing heat sink or a portion of its element which could fit in the space leaved for the heat sink and could dissipate the highest amount of heat generated by the heat-generating device will be chosen. If more than one solution was found, then the one with a minimum manufacturing cost will be picked. None of the inventions mentioned above except for the present one has brought up such an idea so as to save the total costs of a new kind of heat sinks.

Therefore, the purpose of the present invention is to develop a composite heat-dissipating structure to deal with the above situations encountered in the prior arts.

### SUMMARY OF THE INVENTION

It is therefore an object of the present invention to provide a composite heat-dissipating structure which is flexibly assembled and changed without a necessity of redesigning a mold and a circuit board for the composite heat-dissipating structure so as to dissipate the heat generated by the heat-generated device as a response to the practical needs of increasing the assembling possibility of the product, increasing space utilization on and above the circuit board, and reducing the total costs of a new kind of heat sinks with a much shorter designing time of the new heat sink and without the needs of redesigning and manufacturing the mold and the circuit board.

It is another object of the present invention to propose a designing method for the above-mentioned composite heat-dissipating structure.

According to an aspect of the present invention, a composite heat-dissipating structure includes: a first heat-dissipating element detachably connected to a heat-generating device, and a second heat-dissipating element detachably connected to the first heat-dissipating element, wherein the first and second heat-dissipating elements are ones of standard pieces and portions of standard pieces and are flexibly assembled and changed without a necessity of redesigning a mold and a circuit board for the structure so as to dissipate a heat generated by the heat-generating device, and to meet space limitations for the heat-generating device being mounted on the first heat-dissipating element, for the first heat-dissipating element being mounted on the second heat-dissipating element, and for the second heat-dissipating element being mounted on the circuit board.

Preferably, the standard pieces are existing and available heat-dissipating thermal conductive plates with fins.

Preferably, the standard pieces are existing and available heat-dissipating thermal conductive plates without fins.

Preferably, the portions of standard pieces are portions of existing and available heat-dissipating thermal conductive plates with fins.

Preferably, the portions of standard pieces are portions of existing and available heat-dissipating thermal conductive plates without fins.

Preferably, the first heat-dissipating element is a respective standard piece so as to dissipate the heat generated by the heat-generating device from the first heat-dissipating element to the second heat-dissipating element.

Preferably, the second heat-dissipating element is one of standard pieces and portions of standard pieces so as to dissipate the heat generated by the heat-generating device from the second heat-dissipating element to an air.

Preferably, the space limitation for mounting the heat-generating device on the first heat-dissipating element is limited by a space on and above the first heat-dissipating element for the heat-generating device being mounted on the first heat-dissipating element.

Preferably, the space limitation for mounting the first heat-dissipating element on the second heat-dissipating element is limited by a space on and above the second heat-dissipating element for the first heat-dissipating element being mounted on the second heat-dissipating element.

Preferably, the space limitation for mounting the second heat-dissipating element on the circuit board is limited by a space on and above the circuit board for the second heat-dissipating element being mounted on the circuit board.

Preferably, the third heat-dissipating element is detachably connected to the second heat-dissipating element.

Preferably, the third heat-dissipating element is one of the stand pieces and the portions of stand pieces flexibly assembled and changed so as to dissipate the heat generated by the heat-generating device from the third heat-dissipating element to an air and to meet a space limitation for the third heat-dissipating element being mounted on the second heat-dissipating element.

Preferably, the standard pieces are existing and available heat-dissipating thermal conductive plates with fins.

Preferably, the standard pieces are existing and available heat-dissipating thermal conductive plates without fins.

Preferably, the portions of standard pieces are portions of existing and available heat-dissipating thermal conductive plates with fins.

Preferably, the portions of standard pieces are portions of existing and available heat-dissipating thermal conductive plates without fins.

Preferably, the space limitation for the third heat-dissipating element being mounted on the second heat-dissipating element is limited by a space on and above the second heat-dissipating element for the third heat-dissipating element being mounted on the second heat-dissipating element and above the circuit board. Preferably, a composite heat-dissipating structure includes a first heat-dissipating element connected to a heat-generating device and a second heat-dissipating element connected to the first heat-dissipating element, wherein the first and second heat-dissipating elements are one of standard pieces and portions of standard pieces and are flexibly assembled and changed without a necessity of redesigning a mold and a circuit board for the structure so as to dissipate a heat generated by the heat-generating device.

Preferably, the standard pieces are existing and available heat-dissipating thermal conductive plates with fins.

Preferably, the standard pieces are existing and available heat-dissipating thermal conductive plates without fins.

Preferably, the portions of standard pieces are portions of existing and available heat-dissipating thermal conductive plates with fins.

Preferably, the portions of standard pieces are portions of existing and available heat-dissipating thermal conductive plates without fins.

Preferably, the first heat-dissipating element is one of the standard pieces so as to dissipate the heat generated by the heat-generating device from the first heat-dissipating element to the second heat-dissipating element.

Preferably, the second heat-dissipating element is one of standard pieces and portions of standard pieces so as to dissipate the heat generated by the heat-generating device from the second heat-dissipating element to an air.

Preferably, the space limitation for mounting the heat-generating device on the first heat-dissipating element is limited by a space on and above the first heat-dissipating element for the heat-generating device being mounted on the first heat-dissipating element.

Preferably, the space limitation for mounting the first heat-dissipating element on the second heat-dissipating element is limited by a space on and above the second heat-dissipating element for the first heat-dissipating element being mounted on the second heat-dissipating element.

Preferably, the space limitation for mounting the second heat-dissipating element on the circuit board is limited by a space on and above the circuit board for the second heat-dissipating element being mounted on the circuit board.

Preferably, the third heat-dissipating element is connected to the second heat-dissipating element.

Preferably, the third heat-dissipating element is one of the stand pieces and the portions of stand pieces flexibly assembled and changed without a necessity of redesigning a mold and a circuit board for the composite heat-dissipating structure so as to dissipate the heat generated by the heat-generating device from the third heat-dissipating element to an air and to meet a space limitation for the third heat-dissipating element being mounted on the second heat-dissipating element.

Preferably, the standard pieces are existing and available heat-dissipating thermal conductive plates with fins.

Preferably, the standard pieces are existing and available heat-dissipating thermal conductive plates without fins.

Preferably, the portions of standard pieces are portions of existing and available heat-dissipating thermal conductive plates with fins.

Preferably, the portions of standard pieces are portions of existing and available heat-dissipating thermal conductive plates without fins.

Preferably, the space limitation for the third heat-dissipating element being mounted on the second heat-dissipating element is limited by a space on and above the second heat-dissipating element for the third heat-dissipating element being mounted on the second heat-dissipating element and above the circuit board.

According to another aspect of the present invention, a method of designing a composite heat-dissipating structure disposed on a circuit board for a heat-generating device is proposed, wherein the structure includes a first heat-dissipating element connected to a heat-generating device and a second heat-dissipating element connected to the first heat-dissipating element. The method has steps of: (a) computing a heat generated by the heat-generating device, (b) choosing the first heat-dissipating element from one of existing and available heat-dissipating thermal conductive plates which has a space for the heat-generating device being mounted on the first heat-dissipating element and could dissipate the heat generated by the heat-generating device to the second heat-dissipating element through heat conduction, (c) choosing the second heat-dissipating element from one of existing and available heat-dissipating thermal conductive plates such that the first heat-dissipating element could be mounted on the second heat-dissipating element and the second heat-dissipating element could be mounted on the circuit board, is chosen among many so as to dissipate a highest amount of the heat generated by the heat-generating device from the second heat-dissipating element to an air through heat convection, and could dissipate a remaining part of heat generated by the heat-generating device to a third heat-dissipating element through heat conduction, and (d) choosing the second heat-dissipating element from one of portions of existing and available heat-dissipating thermal conductive plates such that the first heat-dissipating element could be mounted on the second heat-dissipating element and the second heat-dissipating element could be mounted on the circuit board, is chosen among many so as to dissipate a highest amount of the heat generated by the heat-generating device from the second heat-dissipating element to the air through heat convection, and could dissipate a remaining part of heat generated by the heat-generating device to the third heat-dissipating element through heat conduction when no solution has been found from the step (c).

Preferably, the step (b) further includes a step (b′) of choosing one with a minimum manufacturing cost when more than one solution has been found from the step (b).

Preferably, the step (c) further includes a step (c′) of choosing one with a minimum manufacturing cost when more than one solution has been found from the step (c).

Preferably, the step (d) further includes a step (d′) of choosing one with a minimum manufacturing cost when more than one solution has been found from the step (d).

Preferably, the many include the existing and available heat-dissipating thermal conductive plates and the portions of existing and available heat-dissipating thermal conductive plates such that the first heat-dissipating element could be mounted thereon to be mounted on the circuit board.

Preferably, the method further includes steps of: (e) choosing the third heat-dissipating element from one of existing and available heat-dissipating thermal conductive plates if a remaining part of the heat generated by the heat-generating device needs to be dissipated from the third heat-dissipating element to the air through heat convection and the third heat-dissipating element could be mounted on the second heat-dissipating element and above the circuit board, and (f) choosing the third heat-dissipating element from one of portions of existing and available heat-dissipating thermal conductive plates if a remaining part of the heat generated by the heat-generating device needs to be dissipated from the third heat-dissipating element to the air through heat convection and the third heat-dissipating element could be mounted on the second heat-dissipating element and above the circuit board when no solution has been found from the step (e).

Preferably, the step (e) further includes a step (e′) of choosing one with a minimum manufacturing cost when more than one solution has been found from the step (e).

Preferably, the step (f) further includes a step (f′) of choosing one with a minimum manufacturing cost when more than one solution has been found from the step (t).

According to another aspect of the present invention, a heat-dissipating system comprising a plurality of composite heat-dissipating structures wherein each of the composite heat-dissipating structure includes: a first heat-dissipating element detachably connected to a heat-generating device, a second heat-dissipating element detachably connected to the first heat-dissipating element, wherein each of the second heat-dissipating element is mounted on a circuit board and is in parallel with the second heat-dissipating elements of the plurality of structures mounted on the circuit board, a third heat-dissipating element detachably connected to the second heat-dissipating element, and a fourth heat-dissipating element integrally connected to said first heat-dissipating element.

Preferably, the first heat-dissipating element is one selected from a group consisting of heat-dissipating thermal conductive plates.

Preferably, the second heat-dissipating element is one selected from a group consisting of heat-dissipating thermal conductive plates and heat sinks.

Preferably, the third heat-dissipating element is one selected from a group consisting of heat-dissipating thermal conductive plates and heat sinks.

Preferably, the fourth heat-dissipating element further includes two basic elements.

Preferably, each of the basic elements includes: a plurality of fins, and a thermal conductive plate wherein each of the plurality of fins is integrally connected with the thermal conductive plate.

Preferably, the existing and available heat-dissipating thermal conductive plates are without fins.

Preferably, the portions of existing and available heat-dissipating thermal conductive plates are with fins.

Preferably, the first dielectric layer is a barrier layer.

Preferably, the portions of existing and available heat-dissipating thermal conductive plates are without fins.

### BRIEF DESCRIPTION OF THE DRAWINGS

FIGS. 1A-1C are diagrams illustrating a heat-dissipating structure according to the prior art;

FIG. 2 is a diagram illustrating a composite heat-dissipating structure according to a preferred embodiment of the present invention; and

FIG. 3 is a diagram illustrating a composite heat-dissipating system according to a preferred embodiment of the present invention.

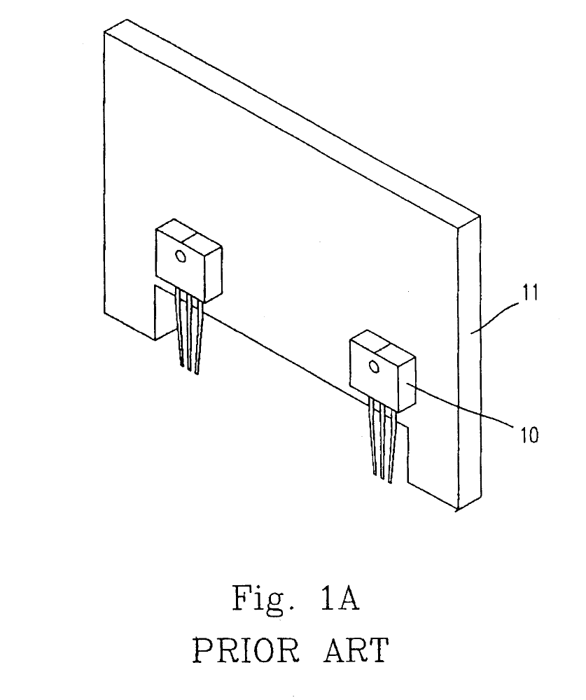

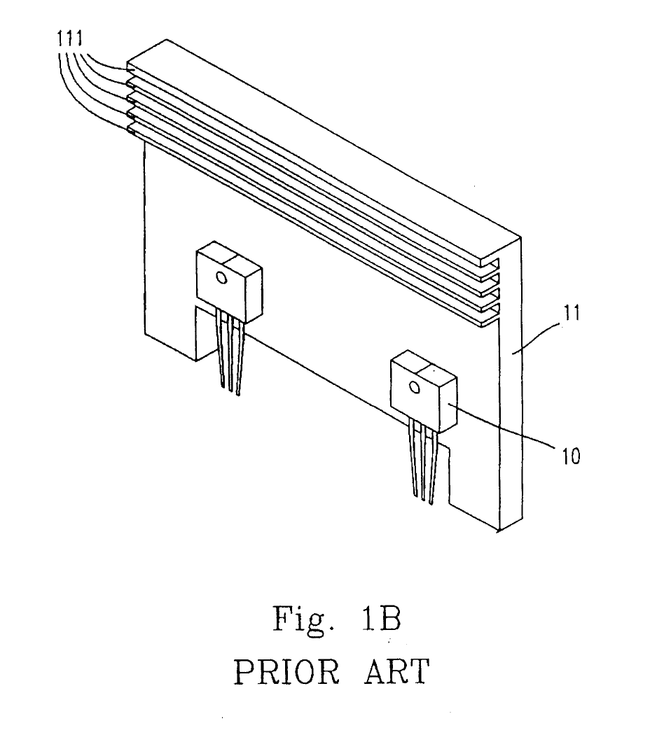

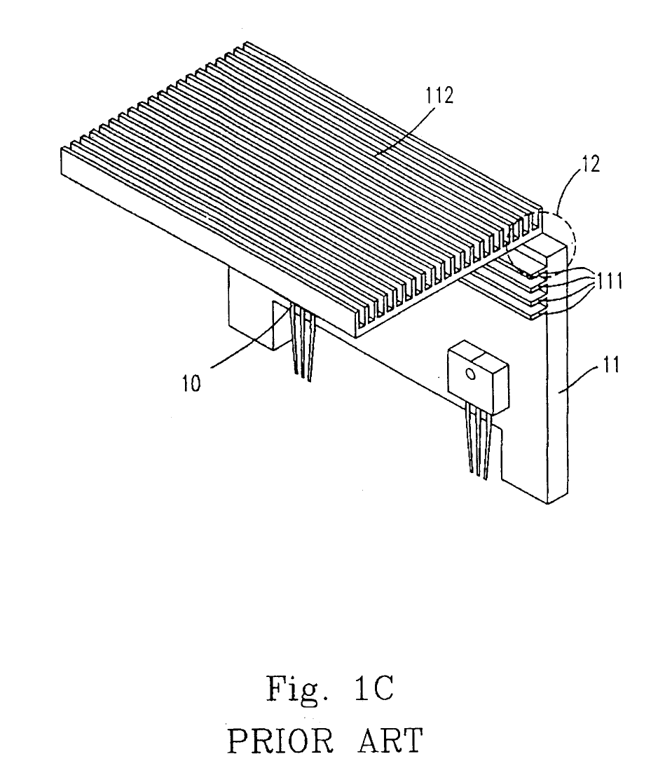

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only; it is not intended to be exhaustive or to be limited to the precise form disclosed.

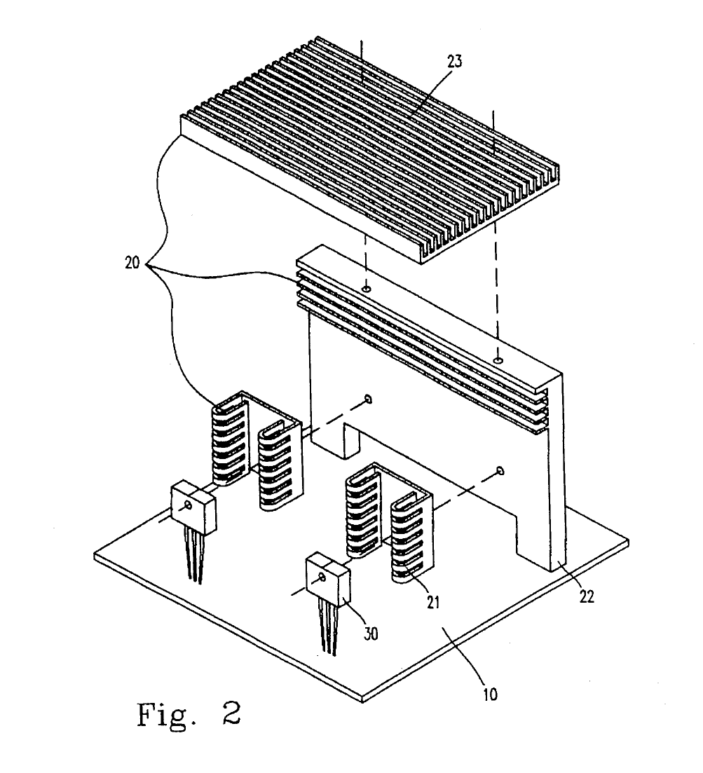

As shown in FIG. 2, the present invention provides a composite heat-dissipating structure applied on a circuit broad 10. The composite heat-dissipating structure 20 includes a first heat-dissipating thermal conductive plate 21 connected to a heat-generating device 30, a second heat-dissipating thermal conductive plate 22 connected to the first heat-dissipating thermal conductive plate 21, and a third heat-dissipating thermal conductive plate 23 connected to the second heat-dissipating thermal conductive plate 22. The first, second and third heat-dissipating thermal conductive plates 21, 22, and 23 are different types of thermal conductive plates in different shapes, different sizes and different specifications. The thermal conductive plates in different specifications are distinguished by different thermal conductivities.

The selection of heat-dissipating thermal conductive plates is dependent on the heat-generating rate of the heat-generating device and the space limitation on and above the circuit broad. The first 21, second 22 and third heat-dissipating thermal conductive plates 23 are either standard pieces or portions of standard pieces and are flexibly assembled and changed without a necessity of redesigning a mold and a circuit board for the structure so as to dissipate a heat generated by the heat-generating device, and to meet space limitations for the heat-generating device being mounted on the first heat-dissipating thermal conductive plate 21, for the first heat-dissipating thermal conductive plate 21 being mounted on the second heat-dissipating thermal conductive plate 22, and for the second heat-dissipating thermal conductive plate 22 being mounted on the circuit board 10.

The first heat-dissipating thermal conductive plate 21 is chosen from existing and available heat-dissipating thermal conductive plates which has a space for the heat-generating device 30 being mounted on the first heat-dissipating thermal conductive plate 21 and could dissipate the heat generated by the heat-generating device 30 to the second heat-dissipating thermal conductive plate 22 through heat conduction.

The second heat-dissipating thermal conductive plate 22 is chosen firstly from existing and available heat-dissipating thermal conductive plates, and secondly from portions of existing and available heat-dissipating thermal conductive plates such that the first heat-dissipating thermal conductive plate 21 could be mounted on the second heat-dissipating thermal conductive plate 22 and the second heat-dissipating thermal conductive plate 22 could be mounted on the circuit board 10, and is chosen among many so as to dissipate a highest amount of the heat generated by the heat-generating device 30 from the second heat-dissipating thermal conductive plate 22 to an air through heat convection, and could dissipate a remaining part of heat generated by the heat-generating device 30 to a third heat-dissipating thermal conductive plate 23 through heat conduction.

The third heat-dissipating thermal conductive plate 23 is chosen firstly from existing and available heat-dissipating thermal conductive plates, and secondly from portions of existing and available heat-dissipating thermal conductive plates if a remaining part of the heat generated by the heat-generating device 30 needs to be dissipated from the third heat-dissipating thermal conductive plate 23 to the air through heat convection and the third heat-dissipating thermal conductive plate 23 could be mounted on the second heat-dissipating element 22 and above the circuit board 10.

If there is more than one solution for each of the first, second and third heat-dissipating elements, the one with a minimum manufacturing cost is chosen.

Hence, the composite heat-dissipating structure 20 can be designed according to the particular requirements of the heat-generation devices on the circuit board in order to achieve the cooling effect. Thus, the circuit broad 10 can normally operate under a proper temperature.

Moreover, the first heat-dissipating thermal conductive plate 21 is connected to the heat-generating devices 20 and is connected to the second heat-dissipating thermal conductive plate 22 by screws. The second heat-dissipating thermal conductive plate 22 is also connected to the third heat-dissipating thermal conductive plate 23 by screws.

Furthermore, a thermal conductive medium such as a cooling ointment is applied into the contact surfaces and points between the heat-generating device 20 and the first heat-dissipating thermal conductive plate 21, between those heat-dissipating thermal conductive plates 21, 22, and between the second heat-dissipating thermal conductive plate 22 and the third heat-dissipating thermal conductive plate 23 for enhancing the heat conduction from the heat-generating device 20 to the heat-dissipating thermal conductive plates 21, 22, and 23. In addition, the heat-dissipating thermal conductive plates 21, 22, and 23 are made of metal.

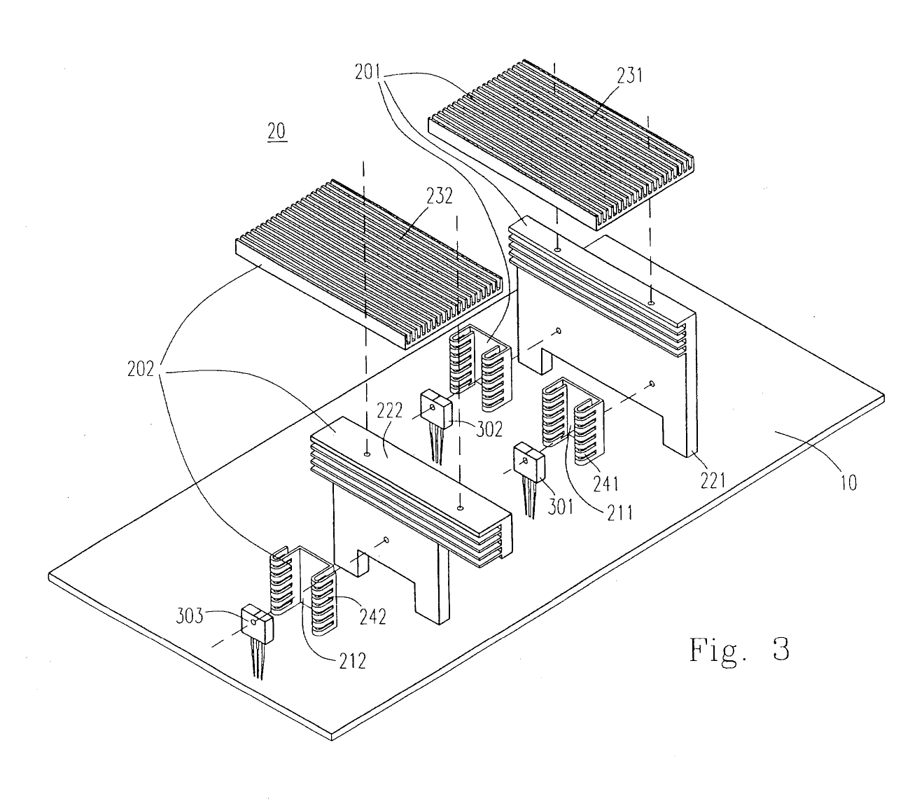

As shown in FIG. 3, the present invention provides a composite heat-dissipating system applied on a circuit broad 10. The composite heat-dissipating system 20 includes a first heat-dissipating structure 201 having a first thermal conductive plate 211 connected to a heat-generating device 301, a second heat-dissipating thermal conductive plate 221 connected to the first heat-dissipating thermal conductive plate 211, a third heat-dissipating thermal conductive plate 231 connected to the second heat-dissipating thermal conductive plate 221, and a fourth heat-dissipating thermal conductive plate with fins 241 integrally connected to the first heat-dissipating thermal conductive plate 211 and a second heat-dissipating structure 202 having a first thermal conductive plate 212 connected to a heat-generating device 303, a second heat-dissipating thermal conductive plate 222 connected to the first heat-dissipating thermal conductive plate 212, a third heat-dissipating thermal conductive plate 232 connected to the second heat-dissipating thermal conductive plate 222, and a fourth heat-dissipating thermal conductive plate with fins 242 integrally connected to the first heat-dissipating thermal conductive plate 212. In the proposed heat-dissipating system, each second heat-dissipating thermal conductive plate like 221 of the composite heat-dissipating structure 201 is in parallel with any other second heat-dissipating thermal conductive plates of the rest of structures belonging to the same heat-dissipating system like 222 of the composite heat-dissipating structure 202. The first, second, third, and fourth heat-dissipating thermal conductive plates of the structures of the proposed heat-dissipating system like 211, 212, 221, 222, 231, 232, 241 and 242 are different types of thermal conductive plates in different shapes, different sizes and different specifications. These thermal conductive plates in different specifications are distinguished by different thermal conductivities

In conclusion, the composite heat-dissipating structure according to the present invention can efficiently solve the problems of the prior arts and has the following advantages of increasing the assembling possibility of the product, increasing space utilization, and reducing the total costs of manufacturing a new kind of heat sinks.

While the invention has been described in terms of what are presently considered to be the most practical and preferred embodiments, it is to be understood that the invention need not to be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A composite heat-dissipating structure, comprising:
a first heat-dissipating element detachably connected to a heat-generating device;
a second heat-dissipating element detachably connected to said first heat-dissipating element, wherein said first and second heat-dissipating elements are ones of standard pieces and portions of standard pieces and are flexibly assembled and changed without a necessity of redesigning a mold and a circuit board for said structure so as to dissipate a heat generated by said heat-generating device, and to meet space limitations for said heat-generating device being mounted on said first heat-dissipating element, for said first heat-dissipating element being mounted on said second heat-dissipating element, and for said second heat-dissipating element being mounted on said circuit board.

2. The composite heat-dissipating structure according to claim 1 wherein said standard pieces are one of existing and available heat-dissipating thermal conductive plates with fins and without fins.

3. The composite heat-dissipating structure according to claim 1 wherein said portions of standard pieces are one of portions of existing and available heat-dissipating thermal conductive plates with fins and without fins.

4. The composite heat-dissipating structure according to claim 1 wherein said first heat-dissipating element is a said respective standard piece so as to dissipate said heat generated by said heat-generating device from said first heat-dissipating element to said second heat-dissipating element.

5. The composite heat-dissipating structure according to claim 1 wherein said second heat-dissipating element is one of standard pieces and portions of standard pieces so as to dissipate said heat generated by said heat-generating device from said second heat-dissipating element to an air.

6. The composite heat-dissipating structure according to claim 1 wherein said space limitation for mounting said heat-generating device on said first heat-dissipating element is limited by a space on and above said first heat-dissipating element for said heat-generating device being mounted on said first heat-dissipating element.

7. The composite heat-dissipating structure according to claim 1 wherein said space limitation for mounting said first heat-dissipating element on said second heat-dissipating element is limited by a space on and above said second heat-dissipating element for said first heat-dissipating element being mounted on said second heat-dissipating element.

8. The composite heat-dissipating structure according to claim 1 wherein a space limitation for mounting said second heat-dissipating element on said circuit board is limited by a space on and above said circuit board for said second heat-dissipating element being mounted on said circuit board.

9. The composite heat-dissipating structure according to claim 1 further comprising a third heat-dissipating element detachably connected to said second heat-dissipating element.

10. The composite heat-dissipating structure according to claim 9 wherein said third heat-dissipating element is one of said stand pieces and said portions of stand pieces flexibly assembled and changed so as to dissipate said heat generated by said heat-generating device from said third heat-dissipating element to an air and to meet a space limitation for said third heat-dissipating element being mounted on said second heat-dissipating element.

11. The composite heat-dissipating structure according to claim 10 wherein said standard pieces are one of existing and available heat-dissipating thermal conductive plates with fins and without fins.

12. The composite heat-dissipating structure according to claim 10 wherein said portions of standard pieces are one of portions of existing and available heat-dissipating thermal conductive plates with fins and without fins.

13. The composite heat-dissipating structure according to claim 10 wherein said space limitation for said third heat-dissipating element being mounted on said second heat-dissipating element is limited by a space on and above said second heat-dissipating element for said third heat-dissipating element being mounted on said second heat-dissipating element and above said circuit board.

14. A composite heat-dissipating structure, comprising:
a first heat-dissipating element connected to a heat-generating device; and
a second heat-dissipating element connected to said first heat-dissipating element, wherein said first and second heat-dissipating elements are one of standard pieces and portions of standard pieces and are flexibly assembled and changed without a necessity of redesigning a mold and a circuit board for said structure so as to dissipate a heat generated by said heat-generating device.

15. A method of designing a composite heat-dissipating structure disposed on a circuit board for a heat-generating device, wherein said structure includes a first heat-dissipating element connected to a heat-generating device and a second heat-dissipating element connected to said first heat-dissipating element, comprising steps of:
(a) computing a heat generated by said heat-generating device;
(b) choosing said first heat-dissipating element from one of existing and available heat-dissipating thermal conductive plates which has a space for said heat-generating device being mounted on said first heat-dissipating element and could dissipate said heat generated by said heat-generating device to said second beat-dissipating element through heat conduction;
(c) choosing said second heat-dissipating element from one of existing and available heat-dissipating thermal conductive plates such that said first heat-dissipating element could be mounted on said second heat-dissipating element and said second heat-dissipating element could be mounted on said circuit board, is chosen among many so as to dissipate a highest amount of said heat generated by said heat-generating device from said second heat-dissipating element to an air through heat convection, and could dissipate a remaining part of heat generated by said heat-generating device to a third heat-dissipating element through heat conduction; and
(d) choosing said second heat-dissipating element from one of portions of existing and available heat-dissipating thermal conductive plates such that said first heat-dissipating element could be mounted on said second heat-dissipating element and said second heat-dissipating element could be mounted on said circuit board, is chosen among many so as to dissipate a highest amount of said heat generated by said heat-generating device from said second heat-dissipating element to said air through heat convection, and could dissipate a remaining part of heat generated by said heat-generating device to said third heat-dissipating element through heat conduction when no solution has been found from said step (c).

16. The method according to claim 15 wherein said step (b) further comprising a step (b′) of choosing one with a minimum manufacturing cost when more than one solution has been found from said step (b).

17. The method according to claim 15 wherein said step (c) further comprising a step (c′) of choosing one with a minimum manufacturing cost when more than one solution has been found from said step (c).

18. The method according to claim 15 wherein said step (d) further comprising a step (d′) of choosing one with a minimum manufacturing cost when more than one solution has been found from said step (d).

19. The method according to claim 15, wherein said many include said existing and available heat-dissipating thermal conductive plates and said portions of existing and available heat-dissipating thermal conductive plates such that said first heat-dissipating element could be mounted thereon to be mounted on said circuit board.

20. The method according to claim 15, further comprising steps of:
(e) choosing said third heat-dissipating element from one of existing and available heat-dissipating thermal conductive plates if a remaining part of said heat generated by said heat-generating device needs to be dissipated from said third heat-dissipating element to said air through heat convection and said third heat-dissipating element could be mounted on said second heat-dissipating element and above said circuit board; and
(f) choosing said third heat-dissipating element from one of portions of existing and available heat-dissipating thermal conductive plates if a remaining part of said heat generated by said heat-generating device needs to be dissipated from said third heat-dissipating element to said air through heat convection and said third heat-dissipating element could be mounted on said second heat-dissipating element and above said circuit board when no solution has been found from said step (e).

21. The method according to claim 20 wherein said step (e) further comprising a step (e′) of choosing one with a minimum manufacturing cost when more than one solution has been found from said step (e).

22. The method according to claim 20 wherein said step (f) further comprising a step (f′) of choosing one with a minimum manufacturing cost when more than one solution has been found from said step (f).

23. A heat-dissipating system comprising a plurality of composite heat-dissipating structures wherein each said composite heat-dissipating structure comprising:
a first heat-dissipating element detachably connected to a heat-generating device;
a second heat-dissipating element detachably connected to said first heat-dissipating element, wherein each said second heat-dissipating element is mounted on a circuit board and is in parallel with said second heat-dissipating elements of said plurality of structures mounted on said circuit board;
a third heat-dissipating element detachably connected to said second heat-dissipating element; and
a fourth heat-dissipating element integrally connected to said first heat-dissipating element.

24. The heat-dissipating system according to claim 23 wherein said first heat-dissipating element is one selected from a group consisting of heat-dissipating thermal conductive plates.

25. The heat-dissipating system according to claim 23 wherein said second heat-dissipating element is one selected from a group consisting of heat-dissipating thermal conductive plates and heat sinks.

26. The heat-dissipating system according to claim 23 wherein said third heat-dissipating element is one selected from a group consisting of heat-dissipating thermal conductive plates and heat sinks.

27. The heat-dissipating system according to claim 23 wherein said fourth heat-dissipating element further comprises two basic elements.

28. The heat-dissipating system according to claim 27 wherein each said basic element comprising:
a plurality of fins; and
a thermal conductive plate wherein each said plurality of fins is integrally connected with said thermal conductive plate.
